(19) United States
(12) Patent Application Publication
(10) Pub. No.: US 2021/0327918 A1
(43) Pub. Date: Oct. 21, 2021

(54) WIRE STRUCTURE OF DISPLAY PANEL AND DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Yangfeng OU, Wuhan (CN)

(21) Appl. No.: 16/317,291

(22) PCT Filed: Dec. 20, 2018
(86) PCT No.: PCT/CN2018/122347

§ 371 Date: Jan. 11, 2019

(30) Foreign Application Priority Data
Sep. 17, 2018 (CN) 201811080594.6

(51) Int. Cl. H01L 27/12

(52) U.S. Cl. CPC H01L 27/1244

(57) ABSTRACT

A wire structure of a display panel and a display panel are provided. The display panel includes an array substrate including a display area and a peripheral area surrounding the display area. The wire structure of the display panel is disposed in the peripheral area of the array substrate and includes a first wire and a second wire. The second wire includes at least one second wire pin and at least one second connection terminal. The first wire and the at least one second wire pin are positioned in different layer planes.

### FIELD OF INVENTION

The present disclosure relates to the field of display technologies, and more particularly to a wire structure of a display panel and a display panel.

### BACKGROUND OF INVENTION

With development of display technologies, users have higher and higher requirements for product resolution, and high resolution requires more dense wiring. In the prior art, a wiring pattern of wire structure of a display panel is in accordance with narrow wire width requirements, where adjacent wires are affected by narrow spacing, and short circuiting easily occurs therebetween.

Therefore, there is a need to provide a wire structure of a display panel and a display panel to solve technical problems of the prior art.

### SUMMARY OF INVENTION

In order to solve the above technical problems, an object of the present disclosure is to provide a wire structure of a display panel and a display panel, which can avoid short circuit of the wire structure of the display panel and improve wiring yield by a first wire and at least one second wire pin positioned in different layer planes.

To achieve the above object, an embodiment of the present disclosure provides a wire structure of a display panel. The display panel includes an array substrate including a display area and a peripheral area surrounding the display area. The wire structure of the display panel is disposed in the peripheral area of the array substrate and includes a first wire and a second wire. The first wire includes at least one first wire pin and at least one first connection terminal connected to the at least one first wire pin. The second wire includes at least one second wire pin and at least one second connection terminal connected to the at least one second wire pin. The first wire and the at least one second wire pin are positioned in different layer planes. The first wire and the at least one second wire pin are positioned in mutually parallel planes. The first wire is positioned in an upper plane, the at least one second wire pin is positioned in a lower plane, and the upper plane is positioned above the lower plane. The at least one second wire pin includes at least one leg and at least one connection segment connected to the at least one leg, and the at least one leg forms an included angle with the at least one connection segment.

In an embodiment of the present disclosure, the included angle is approximately equal to 90 degrees.

In an embodiment of the present disclosure, a length of the at least one connection segment is approximately equal to a distance between the first wire and the at least one second wire pin.

In an embodiment of the present disclosure, the at least one second connection terminal is connected to the at least one connection segment.

In an embodiment of the present disclosure, the at least one first connection terminal and the at least one second connection terminal are in a same plane.

In an embodiment of the present disclosure, the at least one first connection terminal and the at least one second connection terminal are staggered.

According to an embodiment of the present disclosure, a wire structure of a display panel is provided. The display panel includes an array substrate including a display area and a peripheral area surrounding the display area. The wire structure of the display panel is disposed in the peripheral area of the array substrate and includes a first wire and a second wire. The first wire includes at least one first wire pin and at least one first connection terminal connected to the at least one first wire pin. The second wire includes at least one second wire pin and at least one second connection terminal connected to the at least one second wire pin. The first wire and the at least one second wire pin are positioned in different layer planes.

In an embodiment of the present disclosure, the first wire and the at least one second wire pin are positioned in mutually parallel planes.

In an embodiment of the present disclosure, the first wire is positioned in an upper plane, the at least one second wire pin is positioned in a lower plane, and the upper plane is positioned above the lower plane.

In an embodiment of the present disclosure, the at least one second wire pin includes at least one leg and at least one connection segment connected to the at least one leg, and the at least one leg forms an included angle with the at least one connection segment.

In an embodiment of the present disclosure, the included angle is approximately equal to 90 degrees.

In an embodiment of the present disclosure, a length of the at least one connection segment is approximately equal to a distance between the first wire and the at least one second wire pin.

In an embodiment of the present disclosure, the at least one second connection terminal is connected to the at least one connection segment.

In an embodiment of the present disclosure, the at least one first connection terminal and the at least one second connection terminal are in a same plane.

In an embodiment of the present disclosure, the at least one first connection terminal and the at least one second connection terminal are staggered.

According to an embodiment of the present disclosure, a display panel includes an array substrate and a wire structure of the display panel. The array substrate includes a display area and a peripheral area surrounding the display area. The wire structure of the display panel is disposed in the peripheral area of the array substrate and includes a first wire and a second wire. The first wire includes at least one first wire pin and at least one first connection terminal connected to the at least one first wire pin. The second wire includes at least one second wire pin and at least one second connection terminal connected to the at least one second wire pin. The first wire and the at least one second wire pin are positioned in different layer planes.

In an embodiment of the present disclosure, the first wire and the at least one second wire pin are positioned in mutually parallel planes.

In an embodiment of the present disclosure, the first wire is positioned in an upper plane, the at least one second wire pin is positioned in a lower plane, and the upper plane is positioned above the lower plane.

In an embodiment of the present disclosure, the at least one second wire pin includes at least one leg and at least one connection segment connected to the at least one leg, and the at least one leg forms an included angle with the at least one connection segment.

In an embodiment of the present disclosure, the included angle is approximately equal to 90 degrees.

Compared with the prior art, in order to solve the above technical problems, the wire structure of the display panel and the display panel can avoid short circuit of the wire structure of the display panel and improve wiring yield by the first wire and the at least one second wire pin positioned in different layer planes.

### DESCRIPTION OF DRAWINGS

FIG. 1 is a schematic structural view of a wire structure of a display panel according to an embodiment of the present disclosure.

FIG. 2 is a schematic structural view of a wire structure of a display panel according to an embodiment of the present disclosure.

### DETAILED DESCRIPTION OF PREFERRED EMBODIMENTS

The following description of the various embodiments is provided to illustrate the specific embodiments.

In order to make the above description of the present disclosure more comprehensible, preferred embodiments are described below, and are described in detail below with reference to the accompanying drawings.

The above and other objects, features, and advantages of the present disclosure will becomes better understood with reference to the following detailed description considered in connection with the accompanying drawings. Furthermore, directional terms described by the present disclosure, such as up, down, top, bottom, front, back, left, right, inner, outer, side, surrounding, center, horizontal, vertical, longitudinal, axial, radial, uppermost or lowermost, etc., are only directions by referring to the accompanying drawings, and thus the used terms are used only for the purpose of describing embodiments of the present disclosure and are not intended to be limiting of the present disclosure.

In the drawings, units with similar structures are labeled with the same reference number.

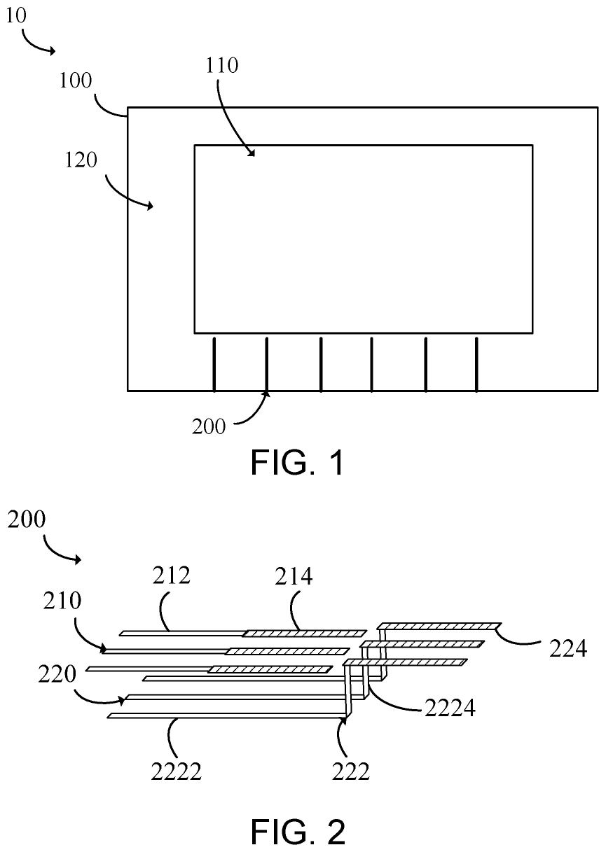

Referring to FIGS. 1 and 2, in an embodiment of the present disclosure, a display panel 10 includes an array substrate 100 and a wire structure 200 of the display panel 10. The array substrate 100 includes a display area 110 and a peripheral area 120 surrounding the display area 110. The wire structure 200 of the display panel 10 is disposed in the peripheral area 120 of the array substrate 100 and includes a first wire 210 and a second wire 220. The first wire 210 includes at least one first wire pin 212 and at least one first connection terminal 214 connected to the at least one first wire pin 212. The second wire 220 includes at least one second wire pin 222 and at least one second connection terminal 224 connected to the at least one second wire pin 222. The first wire 210 and the at least one second wire pin 222 are positioned in different layer planes. The wire structure 200 of the display panel 10 of the embodiment of the present disclosure can avoid short circuit of the wire structure 200 of the display panel 10 and improve wiring yield by the first wire 210 and the at least one second wire pin 222 positioned in different layer planes.

In details, the first wire 210 and the at least one second wire pin 222 are positioned in mutually parallel planes. For example, the first wire 210 is positioned in an upper plane, the at least one second wire pin 222 is positioned in a lower plane, and the upper plane is positioned above the lower plane.

In details, the at least one second wire pin 222 includes at least one leg 2222 and at least one connection segment 2224 connected to the at least one leg 2222, and the at least one leg 2222 forms an included angle with the at least one connection segment 2224. The included angle is, for example, approximately equal to 90 degrees.

In details, a length of the at least one connection segment 2224 is approximately equal to a distance between the first wire 210 and the at least one second wire pin 222. The at least one second connection terminal 224 is connected to the at least one connection segment 2224. The at least one first connection terminal 214 and the at least one second connection terminal 224 are in a same plane. The at least one first connection terminal 214 and the at least one second connection terminal 224 are staggered. In details, for example, the at least one first connection terminal 214 and the at least one second connection terminal 224 are staggered in a first direction, and the at least one first connection terminal 214 and the at least one second connection terminal 224 are arranged in a second direction. The first direction is perpendicular to the second direction.

In details, the at least one first wire pin 212 is a plurality of first wire pins 212 and the at least one second wire pin 222 is a plurality of second wire pins 222. Because the first wire 210 and the at least one second wire pin 222 in the embodiment of the present disclosure are positioned in different layer planes, which can effectively separate the first wire 210 from the at least one second wire pin 222. Therefore, spacing between each first wire pin 212 and adjacent first wire pin 212 can be increased and spacing between each second wire pin 222 and adjacent second wire pin 222 can be increased, thereby reducing process capability requirements of a panel wiring device.

The wire structure of the display panel in the embodiment of the present disclosure can be applied to a high-resolution display panel and a wiring requirement conforming to a narrow line width, and the practical application requirement is high. The display panel in the embodiment of the present disclosure has high resolution, a wiring requirement conforming to a narrow line width, and has high practical application requirements.

In summary, the wire structure of the display panel and the display panel in the embodiment of the present disclosure can avoid short circuit of the wire structure of the display panel and improve wiring yield by the first wire and the at least one second wire pin positioned in different layer planes.

Although the present disclosure is described via one or more embodiments, those of ordinary skill in the art can come up with equivalent variations and modifications based upon the understanding of the specification and the accompanying drawings. The present disclosure includes all such modifications and variations, and is only limited by the scope of the appended claims. In particular, as to the various functions performed by the components described above, the terms used to describe the components are intended to correspond to any component performing the specific functions (e.g., which are functionally equivalent) of the components (unless otherwise indicated), even those which are structurally different from the disclosed structure for performing the functions in the exemplary embodiments in the specification shown herein. In addition, although a particular feature in the specification is disclosed in only one of many embodiments, this feature may be combined with one or more features in other embodiments which are desirable and advantageous to a given or particular application. Moreover, the terms “include”, “have”, “consist of”, or variations thereof used in the detailed description or the claims are intended to be used in a manner similar to the term “comprising”.

In summary, although the preferable embodiments of the present disclosure have been disclosed above. It should be noted that those of ordinary skill in the art can make a variety of improvements and substitutions on the premise of not deviating from the technical principle of the present disclosure, and these improvements and substitutions should be encompassed within the protection scope of the present disclosure.

1. A wire structure of a display panel, the display panel comprising an array substrate comprising a display area and a peripheral area surrounding the display area, the wire structure of the display panel disposed in the peripheral area of the array substrate and comprising:
a first wire comprising at least one first wire pin and at least one first connection terminal connected to the at least one first wire pin; and
a second wire comprising at least one second wire pin and at least one second connection terminal connected to the at least one second wire pin, the first wire and the at least one second wire pin positioned in different layer planes;
wherein the first wire and the at least one second wire pin are positioned in mutually parallel planes;
wherein the first wire is positioned in an upper plane, the at least one second wire pin is positioned in a lower plane, and the upper plane is positioned above the lower plane;
wherein the at least one second wire pin comprises at least one leg and at least one connection segment connected to the at least one leg, and the at least one leg forms an included angle with the at least one connection segment.

2. The wire structure of the display panel according to claim 1, wherein the included angle is approximately equal to 90 degrees.

3. The wire structure of the display panel according to claim 2, wherein a length of the at least one connection segment is approximately equal to a distance between the first wire and the at least one second wire pin.

4. The wire structure of the display panel according to claim 1, wherein the at least one second connection terminal is connected to the at least one connection segment.

5. The wire structure of the display panel according to claim 4, wherein the at least one first connection terminal and the at least one second connection terminal are in a same plane.

6. The wire structure of the display panel according to claim 5, wherein the at least one first connection terminal and the at least one second connection terminal are staggered.

7. A wire structure of a display panel, the display panel comprising an array substrate comprising a display area and a peripheral area surrounding the display area, the wire structure of the display panel disposed in the peripheral area of the array substrate and comprising:
a first wire comprising at least one first wire pin and at least one first connection terminal connected to the at least one first wire pin; and
a second wire comprising at least one second wire pin and at least one second connection terminal connected to the at least one second wire pin, the first wire and the at least one second wire pin positioned in different layer planes.

8. The wire structure of the display panel according to claim 7, wherein the first wire and the at least one second wire pin are positioned in mutually parallel planes.

9. The wire structure of the display panel according to claim 8, wherein the first wire is positioned in an upper plane, the at least one second wire pin is positioned in a lower plane, and the upper plane is positioned above the lower plane.

10. The wire structure of the display panel according to claim 7, wherein the at least one second wire pin comprises at least one leg and at least one connection segment connected to the at least one leg, and the at least one leg forms an included angle with the at least one connection segment.

11. The wire structure of the display panel according to claim 10, wherein the included angle is approximately equal to 90 degrees.

12. The wire structure of the display panel according to claim 11, wherein a length of the at least one connection segment is approximately equal to a distance between the first wire and the at least one second wire pin.

13. The wire structure of the display panel according to claim 10, wherein the at least one second connection terminal is connected to the at least one connection segment.

14. The wire structure of the display panel according to claim 13, wherein the at least one first connection terminal and the at least one second connection terminal are in a same plane.

15. The wire structure of the display panel according to claim 14, wherein the at least one first connection terminal and the at least one second connection terminal are staggered.

16. A display panel, comprising:
an array substrate comprising a display area and a peripheral area surrounding the display area; and
a wire structure of the display panel disposed in the peripheral area of the array substrate and comprising:
a first wire comprising at least one first wire pin and at least one first connection terminal connected to the at least one first wire pin; and
a second wire comprising at least one second wire pin and at least one second connection terminal connected to the at least one second wire pin, the first wire and the at least one second wire pin positioned in different layer planes.

17. The display panel according to claim 16, wherein the first wire and the at least one second wire pin are positioned in mutually parallel planes.

18. The display panel according to claim 17, wherein the first wire is positioned in an upper plane, the at least one second wire pin is positioned in a lower plane, and the upper plane is positioned above the lower plane.

19. The display panel according to claim 16, wherein the at least one second wire pin comprises at least one leg and at least one connection segment connected to the at least one leg, and the at least one leg forms an included angle with the at least one connection segment.

20. The display panel according to claim 19, wherein the included angle is approximately equal to 90 degrees.
